(19) United States
(12) Patent Application Publication
(10) Pub. No.: US 2024/0087858 A1
(43) Pub. Date: Mar. 14, 2024

(54) CLEANING METHOD AND PLASMA PROCESSING METHOD

(71) Applicant: Tokyo Electron Limited, Tokyo (JP)

(72) Inventors: Junichi SASAKI, Miyagi (JP); Yubin YEO, Icheon-si (KR); Yuki ONODERA, Miyagi (JP); Takamitsu TAKAYAMA, Miyagi (JP)

(73) Assignee: Tokyo Electron Limited, Tokyo (JP)

(21) Appl. No.: 18/518,862

(22) Filed: Nov. 24, 2023

Related U.S. Application Data
(63) Continuation of application No. PCT/JP2022/020773, filed on May 19, 2022.

(30) Foreign Application Priority Data
May 25, 2021 (JP) 2021-087740

(51) Int. Cl. H01J 37/32

(52) U.S. Cl. CPC H01J 37/32853; H01J 2237/334

(57) ABSTRACT

A cleaning method according to the present disclosure includes a first cleaning operation and a second cleaning operation, wherein the first cleaning operation includes: supplying a first processing gas to the interior of the chamber; and cleaning a region including the placement region of the stage by generating a first plasma from the first processing gas in a space defined by the placement region and the electrode, and the second cleaning operation includes: holding a dummy substrate at a predetermined position spaced by a predetermined distance from the placement region to face the placement region; supplying a second processing gas to the interior of the chamber; and cleaning a region including a periphery of the placement region of the stage by generating a second plasma from the second processing gas in a space defined by the dummy substrate held at the predetermined position and the electrode.

### CROSS-REFERENCE TO RELATED APPLICATIONS

This application is a bypass continuation application of international application No. PCT/JP2022/020773 having an international filing date of May 19, 2022 and designating the United States, the international application being based upon and claiming the benefit of priority from Japanese Patent Application No. 2021-087740, filed on May 25, 2021, the entire contents of which are incorporated herein by reference.

### TECHNICAL FIELD

An exemplary embodiment of the disclosure relates to a cleaning method and a plasma processing method.

### BACKGROUND

There is a cleaning method disclosed in Patent Document 1 as a technique for removing deposits adhering to the outer circumference of an electrostatic chuck which is provided inside a chamber of a substrate processing apparatus so as to place a substrate thereon.

### PRIOR ART DOCUMENT

### Patent Document

Patent Document 1: Japanese Laid-Open Patent Publication No. 2011-054825

### SUMMARY

According to an exemplary embodiment of the present disclosure, there is provided a cleaning method in a plasma processing apparatus, wherein the plasma processing apparatus includes a chamber, a stage provided inside the chamber and having a placement region on which a substrate is placed, and an electrode provided to face the placement region, and the cleaning method includes a first cleaning operation and a second cleaning operation, wherein the first cleaning operation includes supplying a first processing gas to an interior of the chamber, and cleaning a region including the placement region of the stage by generating a first plasma from the first processing gas in a space defined by the placement region and the electrode, and the second cleaning operation includes holding a dummy substrate at a predetermined position spaced by a predetermined distance from the placement region to face the placement region, supplying a second processing gas to the interior of the chamber, and cleaning a region including a periphery of the placement region of the stage by generating a second plasma from the second processing gas in a space defined by the dummy substrate held at the predetermined position and the electrode.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating a configuration of a plasma processing apparatus according to an embodiment.

FIG. 2 is a view schematically illustrating a substrate processing system PS according to an exemplary embodiment.

FIG. 3 is a flowchart illustrating a plasma processing method according to an embodiment.

FIG. 4 is a cross-sectional view illustrating an example of a patterned substrate PW that is etched in operation ST1.

FIG. 5 is a view schematically illustrating an interior of a chamber 1 in operation ST2.

FIG. 6 is a view schematically illustrating the interior of the chamber 1 in operation ST5.

FIG. 7 is a view schematically illustrating the interior of the chamber 1 in operation ST6.

FIG. 8 is a graph obtained by plotting a relationship between an in-plane position of a dummy substrate DW and an etching rate of a photoresist layer in each example.

### DETAILED DESCRIPTION

Hereinafter, each embodiment of the present disclosure will be described. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In an exemplary embodiment, a cleaning method is provided.

The cleaning method is a cleaning method in a plasma processing apparatus. The plasma processing apparatus includes a chamber, a stage provided in an interior of the chamber and having a placement region on which a substrate is placed, and an electrode provided to face the placement region. The cleaning method includes a first cleaning operation and a second cleaning operation. The first cleaning operation includes supplying a first processing gas to the interior of the chamber, and generating a first plasma from the first processing gas in a space defined by the placement region and the electrode to clean a region of the stage including the placement region. The second cleaning operation includes holding a dummy substrate at a predetermined position spaced by a predetermined distance from the placement region to face the placement region, supplying the second processing gas to the interior of the chamber, and generating a second plasma from the second processing gas in a space defined by the dummy substrate and the electrode held at the predetermined position to clean a region including the periphery of the placement region in the stage.

In an exemplary embodiment, the first processing gas includes an oxygen-containing gas.

In an exemplary embodiment, the oxygen-containing gas is an O₂ gas.

In an exemplary embodiment, the second processing gas includes a fluorine-containing gas.

In an exemplary embodiment, the fluorine-containing gas includes a NF₃ gas.

In an exemplary embodiment, the fluorine-containing gas includes a CₓF_{y} gas (where x and y are positive integers).

In an exemplary embodiment, the second processing gas includes an O₂ gas.

In an exemplary embodiment, a modification operation performed between the first cleaning operation and the second cleaning operation is further provided. The modification operation includes supplying a third processing gas to the interior of the chamber, and generating a third plasma from the third processing gas in the space defined by the placement region and the electrode to modify a region including the placement region in the stage.

In an exemplary embodiment, the third processing gas is a nitrogen gas, and the region including the placement region of the stage is nitrided by the third plasma generated from the nitrogen gas.

In an exemplary embodiment, a dummy substrate processing operation of cleaning a dummy substrate is further provided. The dummy substrate processing operation includes loading the dummy substrate to the interior of the chamber, placing the dummy substrate on the placement region, and generating a fourth plasma from a fourth processing gas in the space defined by the dummy substrate and the electrode placed on the placement region to clean at least the dummy substrate. The second cleaning operation is performed after the dummy substrate processing operation.

In an exemplary embodiment, the third processing gas includes a fluorine-containing gas.

In an exemplary embodiment, the fluorine-containing gas includes a NF₃ gas.

In an exemplary embodiment, the fluorine-containing gas includes a C_{c}F_{y} gas (where x and y are positive integers).

In an exemplary embodiment, the third processing gas includes an O₂ gas.

In an exemplary embodiment, the dummy substrate processing operation includes generating the fourth plasma by supplying RF waves having a first frequency and RF waves having a second frequency to the stage or the electrode.

In an exemplary embodiment, the holding the dummy substrate includes moving the dummy substrate placed on the placement region to a predetermined position.

In an exemplary embodiment, in the loading the dummy substrate, the dummy substrate is loaded to the interior of the chamber from the substrate storage, in the holding the dummy substrate, the dummy substrate loaded to the interior of the chamber from the substrate storage is held at the predetermined position. The second cleaning operation further includes, after the cleaning the region including the periphery of the placement region of the stage, unloading the dummy substrate from the interior of the chamber to the substrate storage.

In an exemplary embodiment, the predetermined distance is a distance at which no plasma is generated in the space defined by the dummy substrate held at the predetermined position and the placement region.

In an exemplary embodiment, the predetermined distance is 0.01 mm or more and 1 mm or less from the placement region.

In an exemplary embodiment, in the second cleaning operation, a time period during which the second plasma is generated is 10 seconds or more and 100 seconds or less.

In an exemplary embodiment, the electrode has a plurality of gas passage holes. In the supplying of the second processing gas to the interior of the chamber, the second processing gas is supplied to the interior of the chamber from the gas passage holes.

In an exemplary embodiment, the second plasma has an energy density of 0.1 W/cm² or more and 10 W/cm² or less.

In an exemplary embodiment, the second plasma has a higher energy density than the first plasma.

In an exemplary embodiment, the first cleaning operation includes generating the first plasma by supplying RF waves having a first power to the stage or the electrode, and the second cleaning operation includes generating the second plasma by supplying RF waves having a second power higher than the first power to the stage or the electrode.

In an exemplary embodiment, the second power is 50 W or more and 10,000 W or less.

In an exemplary embodiment, a cleaning method in a plasma processing apparatus is provided. The plasma processing apparatus includes a chamber, a stage provided in an interior of the chamber and having a placement region on which a substrate is placed, and an electrode provided to face the placement region. The cleaning method includes loading a dummy substrate to the interior of the chamber, holding a dummy substrate at a position space by a predetermined distance from the placement region to face the placement region, supplying a processing gas into the chamber, and generating a plasma from the processing gas in a space defined by the dummy substrate and the electrode held at the predetermined position to clean a region including the placement region of the stage.

In an exemplary embodiment, a plasma processing method in a plasma processing apparatus is provided. The plasma processing apparatus includes a chamber, a stage provided in an interior of the chamber and having a placement region on which a substrate is placed, and an electrode provided to face the placement region. The plasma processing method includes an etching operation and a cleaning operation. The etching operation includes preparing a patterned substrate having a layer to be etched and a mask layer formed on the layer to be etched and having a predetermined pattern, placing the patterned substrate on the placement region of the stage, supplying an etching gas to the interior of the chamber, etching the patterned substrate by supplying RF power to the stage or the electrode to generate a plasma from an etching gas in a space defined by the patterned substrate and the electrode, and unloading the patterned substrate from the chamber. The cleaning operation includes loading a dummy substrate different from the patterned substrate into the chamber, holding the dummy substrate at a position spaced by a predetermined distance from the placement region to face the placement region, supplying a processing gas to the interior of the chamber, and generating a plasma from the processing gas in a space defined by the dummy substrate and the electrode held at the predetermined position to clean a region including the periphery of the placement region of the stage.

Hereinafter, each embodiment of the present disclosure will be described in detail with reference to the drawings. In each drawing, the same or similar elements will be denoted by the same reference numerals, and a redundant description thereof will be omitted. Unless otherwise specified, positional relationships such as top, bottom, left, and right will be described based on the positional relationships illustrated in the drawings. The dimensional ratios in the drawings do not indicate the actual ratios, and the actual ratios are not limited to the ratios illustrated in the drawings.

### <Configuration of Plasma Processing Apparatus>

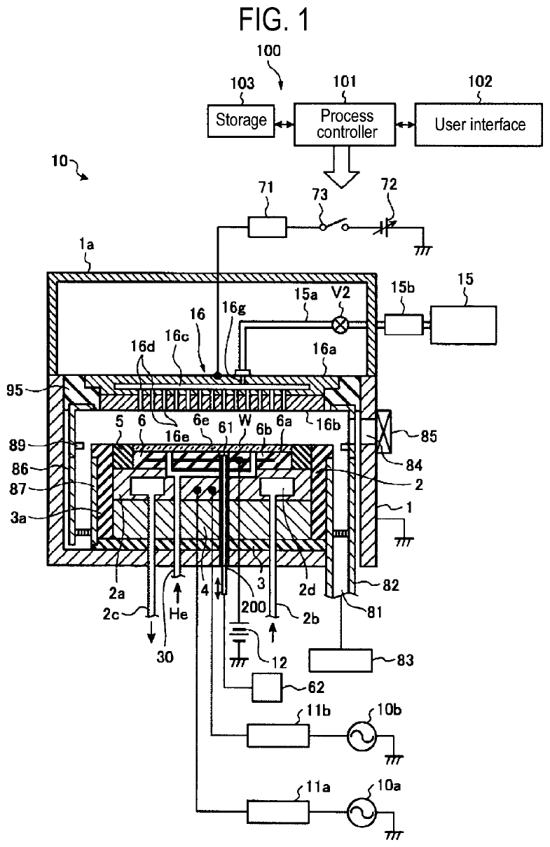

FIG. 1 is a schematic cross-sectional view illustrating a configuration of a plasma processing apparatus 10 according to an embodiment. The plasma processing apparatus 10 includes a chamber 1 that is configured to be airtight and electrically connected to a ground potential. The chamber 1 defines a processing space in which plasma is generated. A stage 2 that supports a substrate W is provided inside the chamber 1. The stage 2 includes a base 2a and an electrostatic chuck (ESC) 6. The base 2a is made of a conductive metal, such as aluminum, and has a function as a lower electrode. The electrostatic chuck 6 has a function of electrostatically adsorbing the substrate W. The electrostatic chuck 6 is arranged on an upper surface of the base 2a. The stage 2 is supported on a support table 4. The support table 4 is supported by a support member 3 made of, for example, quartz.

A focus ring 5 made of, for example, single crystal silicon, is provided on an upper outer periphery of the stage 2. Specifically, the focus ring 5 has an annular shape and is arranged on an upper surface of the base 2a to surround the outer periphery of the placement surface for substrate W on the stage 2 (an upper surface of the electrostatic chuck 6). Inside the chamber 1, a cylindrical inner wall member 3a made of, for example, quartz, is provided to surround the periphery of the stage 2 and the support table 4.

A first RF power supply 10a is connected to the base 2a via a first matcher 11a. In addition, a second RF power supply 10b is connected via a second matcher 11b. The first RF power supply 10a is a power supply for plasma generation. The first RF power supply 10a is configured to supply RF power of a predetermined frequency to the base 2a of the stage 2. In addition, the second RF power supply 10b is a power supply for ion attraction (for bias). The second RF power supply 10b is configured to supply RF power of a predetermined frequency lower than the RF power supplied by the first RF power supply 10a to the base 2a of the stage 2. In this way, the stage 2 is configured to be able to receive voltage. On the other hand, a shower head 16 is provided above the stage 2 to face the stage 2 in parallel. The shower head 16 has a function as an upper electrode. The shower head 16 and the stage 2 function as a pair of electrodes (the upper electrode and the lower electrode).

The upper surface of the electrostatic chuck 6 is configured as a placement surface 6e on which the substrate is placed. The placement surface 6e has a flat disk shape. The electrostatic chuck 6 includes an insulator 6b and an electrode 6a provided inside the insulator 6b. A DC power supply 12 is connected to the electrode 6a. Then, by applying a DC voltage from the DC power supply 12 to the electrode 6a, the substrate W is attracted to the placement surface 6e by virtue of Coulomb force.

In the present embodiment, as an example, the placement surface 6e and the substrate W have a circular shape, and a diameter of the placement surface 6e is smaller than a diameter of the substrate W.

A temperature-regulating-medium flow path 2d is provided inside the stage 2. An inlet pipe 2b and an outlet pipe 2c are connected to the temperature-regulating-medium flow path 2d. A temperature of the stage 2 may be controlled by circulating an appropriate temperature regulating medium, such as cooling water, in the temperature-regulating-medium flow path 2d. In addition, the stage 2 is provided with a gas supply pipe 30 for supplying a cold heat transfer gas (backside gas) such as a helium gas to a rear surface of the substrate W. The gas supply pipe 30 is connected to a gas source (not illustrated). With these configurations, the temperature of the substrate W held by the electrostatic chuck 6 on the placement surface 6e may be controlled to a predetermined temperature.

The stage 2 is provided with a plurality of pin through-holes 200, for example, three pin through-holes 200 (only one is illustrated in FIG. 1). A lifter 61 is provided inside each of these pin through-holes 200. The lifter 61 is connected to an actuator 62. The actuator 62 is able to raise or lower the lifter 61 to cause the lifter 61 to protrude from the placement surface 6e. When the lifter 61 is raised in the state in which the substrate W is placed on the placement surface 6e, a tip of the lifter 61 protrudes from the placement surface 6e of the electrostatic chuck 6 so that the substrate W is held at a predetermined distance from the placement surface 6e of the electrostatic chuck 6. On the other hand, when the lifter 61 is lowered, the tip of the lifter 61 is accommodated in the pin through-hole 200 so that the substrate W is placed on the placement surface 6e of the electrostatic chuck 6. In this way, the actuator 62 is able to control a position of the substrate W with respect to the placement surface 6e of the electrostatic chuck 6 (a position in a direction perpendicular to the placement surface 6e) by the lifter 61.

The shower head 16 is provided in the chamber 1. The shower head 16 includes a main body 16a and an upper ceiling plate 16b that functions as an electrode plate. The shower head 16 is supported on the upper portion of chamber 1 via an insulating member 95. The main body 16a is made of a conductive material, such as aluminum whose surface is anodized. The main body 16a is configured TO detachably support the upper ceiling plate 16b at a lower portion of the main body 16a. One end portion of a gas supply pipe 15a is connected to a gas inlet port 16g. A gas source (gas supplier) 15 that supplies a processing gas is connected to the other end portion of this gas supply pipe 15a. The gas supply pipe 15a is provided with a mass flow controller (MFC) 15b and an opening/closing valve V2 in that order from the upstream side. A processing gas for plasma etching is supplied from the gas source 15 to a gas diffusion chamber 16c via the gas supply pipe 15a. The processing gas is supplied into the chamber 1 from the gas diffusion chamber 16c via gas passage holes 16d and gas introduction holes 16e in the form of a shower.

A variable DC power supply 72 is electrically connected to the shower head 16 via a low pass filter (LPF) 71. The variable DC power supply 72 is configured such that power supply is turned on and off by an on/off switch 73. A current and voltage of the variable DC power supply 72 and an on-off operation of the on/off switch 73 are controlled by a controller 100, which will be described later. As will be described later, when RF waves are applied to the stage 2 from the first RF power supply 10a and the second RF power supply 10b and plasma is generated in the processing space, the on/off switch 73 is turned on by the controller 100, if necessary. As a result, a predetermined DC voltage is applied to the shower head 16 functioning as the upper electrode.

A cylindrical ground conductor 1a is provided to extend from a sidewall of the chamber 1 to a position above a height position of the shower head 16. The cylindrical ground conductor 1a has a ceiling wall on its upper portion.

An exhaust port 81 is provided in a bottom portion of the chamber 1. A first exhaust device 83 is connected to the exhaust port 81 via an exhaust pipe 82. The first exhaust device 83 includes a vacuum pump. By operating this vacuum pump, an internal pressure of the chamber 1 may be reduced to a predetermined pressure. On the other hand, a loading/unloading port 84 for the substrate W is provided in the sidewall of the chamber 1. A gate valve 85 for opening/closing the loading/unloading port 84 is provided at the loading/unloading port 84.

A deposition shield 86 is provided inward of a side portion of the chamber 1 along an inner wall surface of the chamber 1. The deposition shield 86 prevents an etching byproduct (a deposit) from adhering to the chamber 1. A conductive member (GND block) 89 is provided at substantially the same height as the substrate W on the deposition shield 86 such that a potential with respect to the ground can be controlled, thereby preventing abnormal discharge. In addition, a deposition shield 87 is provided around the inner wall member 3a to face a lower end portion of the deposition shield 86. The deposition shields 86 and 87 are detachably provided.

The overall operation of the plasma processing apparatus 10 having the above-described configuration is controlled by the controller 100. The controller 100 is provided with a process controller 101 that includes a CPU and controls each component of the plasma processing apparatus 10, a user interface 102, and a storage 103.

The user interface 102 is constituted with a keyboard that allows a process manager to input commands for managing the plasma processing apparatus 10 therethrough, a display that visually displays the operation situation of the plasma processing apparatus 10, and the like.

The storage 103 stores recipes in which, for example, control programs (software) for implementing various processes executed in the plasma processing apparatus 10 under the control of the process controller 101, processing condition data and the like are stored. If necessary, by calling an arbitrary recipe from the storage 103 by using, for example, an instruction from the user interface 102 and causing the process controller 101 to execute the recipe, a desired process is performed by the plasma processing apparatus 10 under the control of the process controller 101. In addition, the recipes such as control programs or processing condition data may be used in the state of being stored in a computer storage medium (e.g., a hard disc, a CD, a flexible disc, or semiconductor memory) that is capable of being read by a computer. In addition, the recipes such as control programs or processing condition data may be transmitted from other devices at any time via, for example, a dedicated line, and be used online.

### <Configuration of Substrate Processing System PS>

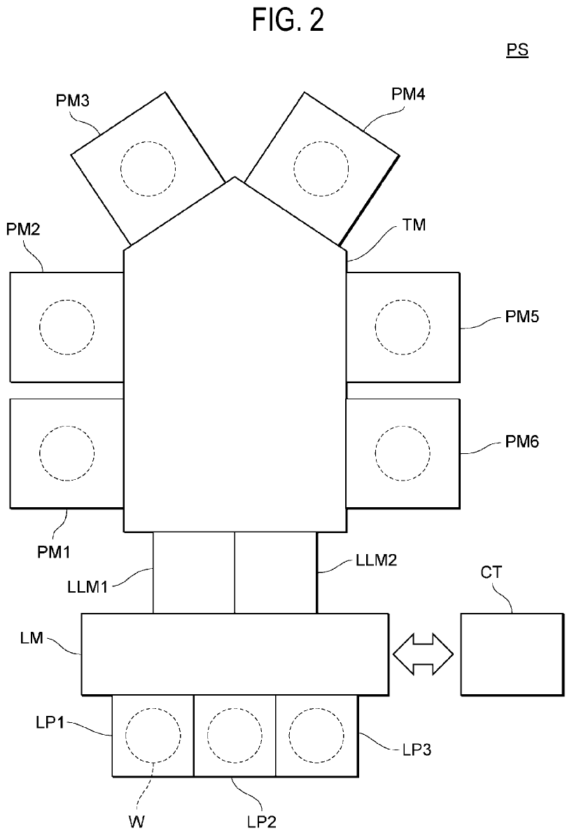

FIG. 2 is a view schematically illustrating a substrate processing system PS according to an exemplary embodiment. The substrate processing system PS includes substrate processing chambers PM1 to PM6 (hereinafter, also collectively referred to as “substrate processing modules PM”), a transfer module TM, and load-lock modules LLM1 and LLM2 (hereinafter, collectively referred to as “load-lock modules LLM”), a loader module LM, and load ports LP1 to LP3 (hereinafter, also collectively referred to as “load ports LP”). The controller CT controls each component of the substrate processing system PS to perform a predetermined process on the substrate W.

The substrate processing modules PM perform therein processes, such as etching, trimming, film formation, annealing, doping, lithography, cleaning, and ashing, on the substrate W. Some of the substrate processing modules PM may be a measurement module, and may measure a thickness of a layer formed on the substrate W, a dimension of a pattern formed on the substrate W, and the like. The plasma processing apparatus 10 illustrated in FIG. 1 is an example of the substrate processing module PM.

The transfer module TM includes a transfer apparatus that transfers substrates W, and transfers the substrates W between the substrate processing modules PM or between the substrate processing modules PM and the load-lock modules LLM. The substrate processing modules PM and the load-lock modules LLM are arranged adjacent to the transfer module TM. The transfer modules TM, the substrate processing modules PM, and the load-lock modules LLM are spatially isolated or connected by gate valves that can be opened and closed.

The load-lock modules LLM1 and LLM2 are provided between the transfer module TM and the loader modules LM. The load-lock modules LLM are able to switch an internal pressure thereof to atmospheric pressure or vacuum. The load-lock modules LLM transfer substrates W from the loader module LM under atmospheric pressure to the transfer module TM under vacuum and also transfers the substrates W from the transfer module TM under vacuum to the loader modules LM under atmospheric pressure.

The loader module LM includes a transfer apparatus that transfers the substrates W, and transfers the substrates W between the load-lock modules LLM and the load ports LP. Inside the load ports LP, a front opening unified pod (FOUP) capable of accommodating, for example, 25 substrates W or an empty FOUP may be placed. The loader modules LM take out the substrates W from the FOUP in the load port LP and transfers the same to the load-lock module LLM. In addition, the loader module LM takes out the substrates W from the load-lock modules LLM and transfers the substrates to the FOUP in the load port LP. At least one of the plurality of load ports LP may have a FOUP that accommodates a dummy board.

The controller CT controls each component of the substrate processing system PS to perform a predetermined process on the substrate W. The controller CT stores a recipe in which process procedures, process conditions, transfer conditions, and the like are set, and controls each component of the substrate processing system PS to perform a predetermined process on the substrate W according to the recipe. The controller CT may also function as a portion or all of the controller 100 of the plasma processing apparatus 10 illustrated in FIG. 1.

### <Plasma Processing>

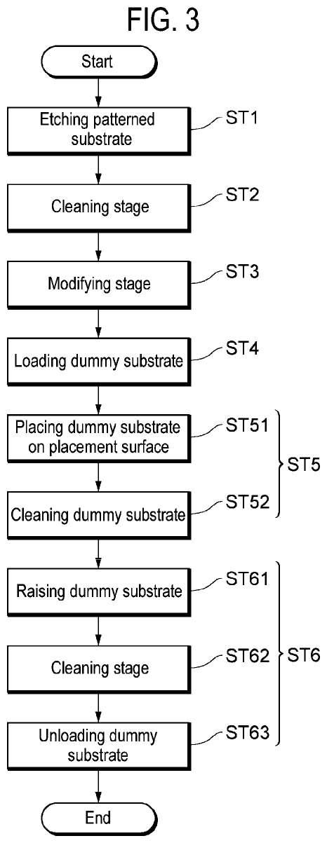

FIG. 3 is a flowchart illustrating a plasma processing method according to an embodiment. The process illustrated in each operation in FIG. 3 is implemented mainly by operating the plasma processing apparatus 10 under the control of the controller 100. The plasma processing method illustrated in FIG. 3 includes an operation of etching a patterned substrate PW (ST1), a first cleaning operation of cleaning the stage 2 (ST2), a modification operation of modifying the placement surface 6e of the electrostatic chuck 6 (ST3), an operation of loading a dummy substrate DW (ST4), an operation of cleaning the dummy substrate DW (ST5), and a second cleaning operation of cleaning the stage 2 (ST6).

In the plasma processing method according to the present embodiment, all the operations illustrated in FIG. 3 are not essential. That is, some of the operations illustrated in FIG. 3 may be omitted. In addition, an order in which the operations illustrated in FIG. 3 are performed may be changed. Hereinafter, an example of a process in each operation illustrated in FIG. 3 will be described with reference to each figure.

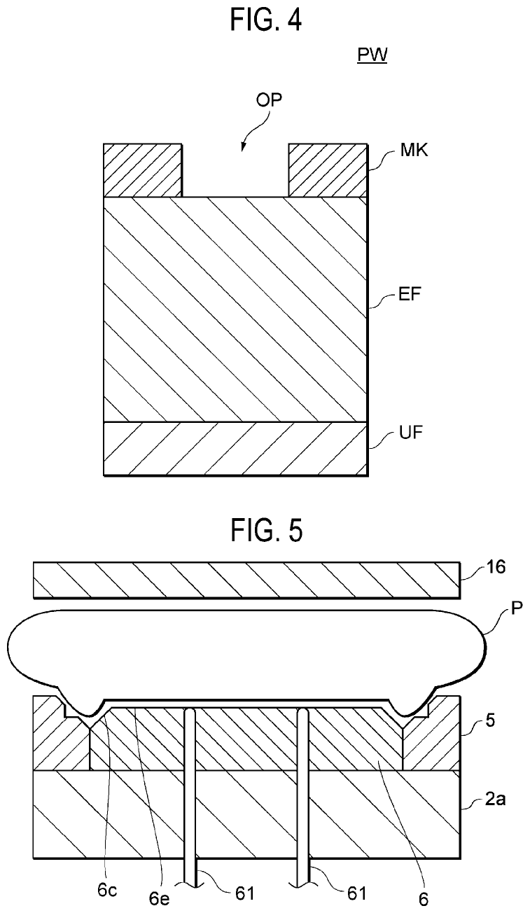

FIG. 4 is a cross-sectional view illustrating an example of the patterned substrate PW that is etched in operation ST1. The patterned substrate PW has a structure in which a base layer UF, a layer to be etched EF, and a mask layer MK are laminated. The base film UF may be, for example, a silicon wafer or an organic layer, a dielectric layer, a metal layer, a semiconductor layer, or the like formed on a silicon wafer (including both a case where the base film is formed on the surface of a silicon wafer and a case where the base film is formed on the surface of another film formed on a silicon wafer). The base layer UF may be configured by laminating a plurality of layers. The layer to be etched EF is, for example, an organic layer or a dielectric layer. The organic layer is, for example, a spin-on carbon layer (SOC), a photoresist layer, or amorphous carbon. The dielectric layer is, for example, a silicon oxide layer, a silicon nitride layer, Si-ARC, or SiON.

The mask layer MK is a layer, such as a photoresist, that functions as a mask during the etching of the layer to be etched EF. The mask layer MK is formed to have at least one sidewall. The sidewall defines at least one recess OP on the layer to be etched EF. The recess OP is a space above the layer to be etched EF and is surrounded by the sidewall. That is, in FIG. 4, the layer to be etched EF has a region covered by the mask layer MK and a region exposed at the bottom of the recess OP.

In operation ST1, first, the patterned substrate PW is transferred into the chamber 1 of the plasma processing apparatus 10. In addition, the patterned substrate PW is placed on the placement surface 6e of the stage 2 by the lifters 61. After a predetermined processing gas is supplied into the chamber 1, RF power is supplied to the stage 2, which is the lower electrode. As a result, plasma is generated from the processing gas in a space between the patterned substrate PW and the shower head 16 functioning as an upper electrode. Then, as active species in the plasma are drawn into the patterned substrate PW so that a portion of the layer to be etched EF exposed in the recess OP of the mask layer MK is etched. After the etching of the patterned substrate PW is completed, the patterned substrate PW is unloaded outward of the chamber 1. In the course of etching the layer to be etched EF, an etching byproduct may be generated. The byproduct adheres to or is deposited to, for example, a periphery of the placement surface 6e of the electrostatic chuck 6.

FIG. 5 is a view schematically illustrating an interior of the chamber 1 in operation ST2. As illustrated in FIG. 5, at least a portion of the electrostatic chuck 6 is cleaned in operation ST2.

That is, first, a predetermined processing gas is supplied into the chamber 1 while no substrate is placed on the stage 2 (i.e., the placement surface 6e is exposed to the shower head 16). At this time, an internal pressure of the chamber 1 is reduced to a predetermined pressure. The processing gas may be appropriately selected depending on the byproduct generated in the etching of the patterned substrate PW (ST1). For example, when the byproduct is a CF-based polymer, the processing gas may be an O₂ gas. In addition, the processing gas is not limited to the O₂ gas, but may be other oxygen-containing gases such as a CO gas, a CO₂ gas, and an O₃ gas). In addition, when silicon or metal is included as a byproduct in addition to the CF-based polymer, for example, a halogen-containing gas may be added to the oxygen-containing gas as the processing gas. The halogen-containing gas is, for example, a fluorine-based gas such as a CF₄ gas or a NF₃ gas. In addition, the halogen-containing gas may be a chlorine-based gas such as a Cl₂ gas or a bromine-based gas such as a HBr gas.

Next, RF power is supplied to the stage 2 which functions as a lower electrode. The controller 100 controls the first RF power supply 10a to generate RF power, thereby supplying the RF power to the base material 2a of the stage 2. As a result, plasma is generated from the processing gas supplied into the chamber 1 in a space defined by the placement surface 6e of the electrostatic chuck 6 and the shower head 16 which functions as an upper electrode. In addition, a frequency of the RF power generated by the first RF power supply 10a may be, for example, 10 MHz or more and 100 MHz or less, or 40 MHz or more and 100 MHz or less. In addition, the RF power may be, for example, 50 W or more and 10,000 W or less, 100 W or more and 7,000 W or less, or 200 W or more and 2,000 W or less.

When the plasma is generated in the space defined by the placement surface 6e and the shower head 16, at least a portion of the electrostatic chuck 6 is cleaned by the plasma. The cleaning may be, for example, removing a byproduct adhering to or deposited on a shoulder 6c of the electrostatic chuck 6 in the etching of the patterned substrate PW (ST1). In addition, the cleaning may be a cleaning operation of removing some of the byproduct, or a cleaning operation of removing all of the byproduct. In addition, the byproduct adhering to or deposited on the inner wall of the chamber 1 may be removed by the plasma generated in the space defined by the placement surface 6e and the shower head 16.

Next, in operation ST3, the placement surface 6e of the electrostatic chuck 6 is modified. In operation ST3, first, a predetermined processing gas is supplied into the chamber 1 while no substrate is placed on the stage 2. At this time, the internal pressure of the chamber 1 is reduced to a predetermined pressure. The processing gas may be, for example, an inert gas. In the present embodiment, the processing gas is a N₂ gas.

RF power is supplied to the stage 2 which functions as a lower electrode. The controller 100 controls the first RF power supply 10a to generate RF power, thereby supplying the RF power to the base material 2a of the stage 2. As a result, plasma is generated from the processing gas supplied into the chamber 1 in a space defined by the placement surface 6e of the electrostatic chuck 6 and the shower head 16 which functions as an upper electrode. In addition, the frequency of the RF power generated by the first RF power supply 10a may be, for example, 10 MHz or more and 100 MHz or less, or 40 MHz or more and 100 MHz or less. In addition, the RF power may be, for example, 50 W or more and 10,000 W or less, 100 W or more and 7,000 W or less, or 200 W or more and 2,000 W or less.

When the plasma is generated in the space defined by the placement surface 6e and the shower head 16, at least a portion of the surface of the electrostatic chuck 6 is modified by the plasma. In the present embodiment, the plasma is generated from the N₂ gas, and the placement surface 6e of the electrostatic chuck 6 is nitrided by the plasma. As a result, fluorine adhering to the placement surface 6e is removed.

Subsequently, in operation ST4, the dummy substrate DW is loaded into the chamber 1. The dummy substrate DW is a substrate, such as a silicon substrate, which does not have a patterned layer on its surface. The dummy substrate DW may be unloaded, for example, from the FOUP (an example of a storage) of the load port LP (see FIG. 2) and loaded into the chamber 1. Moreover, the dummy substrate DW unloaded from the load port LP may be the dummy substrate DW used in operation ST6 which will be described later. That is, the dummy substrate DW loaded into the chamber 1 in operation ST4 may be the dummy substrate DW unloaded to the load port LP after having been used in operation ST6 of the previous cycle.

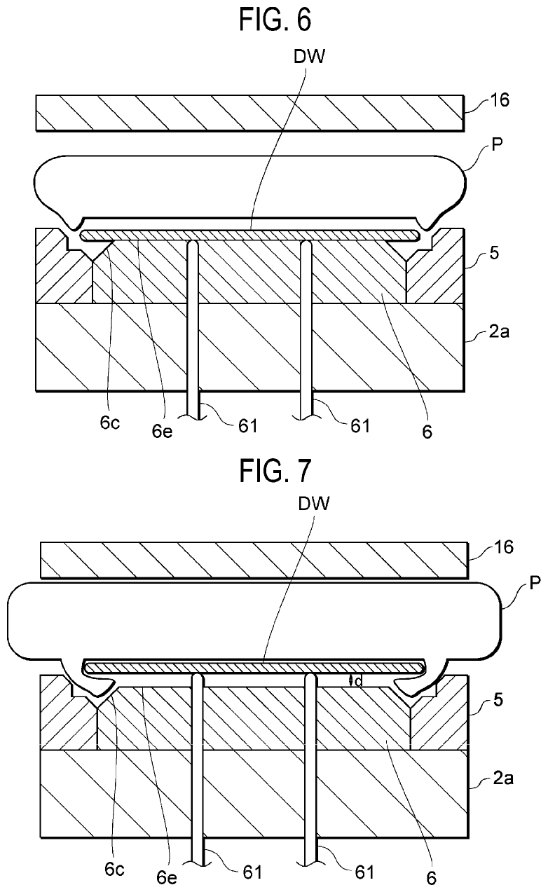

FIG. 6 is a view schematically illustrating the interior of the chamber 1 in operation ST5. As illustrated in FIG. 6, in operation ST5, the dummy substrate DW is cleaned. Operation ST5 includes an operation of placing the dummy substrate DW on the placement surface 6e (ST51) and an operation of cleaning the dummy substrate DW (ST52).

First, the dummy substrate DW loaded into the chamber 1 in operation ST4 is placed on the placement surface 6e in operation ST51. Specifically, the dummy substrate DW is placed on the tips of the lifters 61 in the state in which the lifters 61 protrude from the placement surface 6e. Then, when the lifters 61 are lowered, the dummy substrate DW is placed on the placement surface 6e. Then, when a predetermined voltage is applied to the electrode 6a of the electrostatic chuck 6, the dummy substrate DW is electrostatically attracted to the placement surface 6e.

Subsequently, in operation ST52, the dummy substrate DW is cleaned. First, a predetermined processing gas is supplied into the chamber 1 while the dummy substrate DW is placed on the placement surface 6e. At this time, the internal pressure of the chamber 1 is reduced to a predetermined pressure. The predetermined pressure may be lower than the pressure in operation ST2 and/or the pressure in operation ST3. The processing gas is generated in the etching of the patterned substrate PW (ST1) and may be appropriately selected depending on the byproduct adhering to or deposited on the shoulder 6c of the electrostatic chuck 6. For example, when the byproduct is a CF-based polymer, the byproduct may be a fluorine-containing gas such as NF₃ or CF₄. In addition, the processing gas may include an O₂ gas. In addition, the processing gas is not limited to the O₂ gas, but may be other oxygen-containing gases such as a CO gas, a CO₂ gas, and an O₃ gas). In addition, when silicon or metal is included as a byproduct in addition to the CF-based polymer, for example, a halogen-containing gas may be added as the processing gas. In addition, the halogen-containing gas may be a chlorine-based gas such as a Cl₂ gas or a bromine-based gas such as a HBr gas. In addition, the processing gas may further include, for example, an inert gas such as an Ar gas.

Subsequently, RF power is supplied to the stage 2 which is a lower electrode. The controller 100 controls the first RF power supply 10a and the second RF power supply 10b to generate RF power, thereby applying a first RF power and a second RF power to the base 2a of the stage 2. As a result, plasma is generated from the processing gas supplied into the chamber 1 in the space defined by the dummy substrate DW placed on the placement surface 6e and the shower head 16 which functions as an upper electrode. In addition, a frequency of the RF power generated by the first RF power supply 10a may be, for example, 10 MHz or more and 100 MHz or less, or 40 MHz or more and 100 MHz or less. In addition, the RF power may be, for example, 50 W or more and 10,000 W or less, 100 W or more and 7,000 W or less, or 500 W or more and 7,000 W or less. In addition, a frequency of the RF power generated by the second RF power supply 10b may be, for example, 100 kHz or more and 50 MHz or less, or 400 kHz or more and 13.56 MHz or less. In addition, the RF power may be, for example, 0 W or more and 25,000 W or less, 100 W or more and 25,000 W or less, or 500 W or more and 5,000 W or less.

When the plasma is generated in the space defined by the dummy substrate DW placed on the placement surface 6e and the shower head 16, at least the dummy substrate DW is cleaned by the plasma. The cleaning may be an operation of removing the byproduct adhering to the dummy substrate DW from the shoulder 6c of the electrostatic chuck 6 in operation ST6 of the previous cycle.

FIG. 7 is a view schematically illustrating the interior of the chamber 1 in operation ST6. As illustrated in FIG. 7, in operation ST6, at least a portion of the stage 2 is cleaned while holding the dummy substrate DW at a position spaced by a predetermined distance d from the placement surface 6e. Operation ST6 includes an operation of lifting the dummy substrate DW (ST61), an operation of cleaning the stage 2 (ST62), and an operation of unloading the dummy substrate DW (ST63).

First, in operation ST61, the dummy substrate DW is raised by the lifters 61. Specifically, as illustrated in FIG. 7, the lifters 61 are moved in a direction toward the shower head 16 so that the tips of the lifters 61 protrude from the placement surface 6e. As a result, the dummy substrate DW is raised from the placement surface 6e by the lifters 61, and the dummy substrate DW is held at the position spaced by the predetermined distance d from the placement surface 6e. The dummy substrate DW may be held in parallel to the placement surface 6e.

The distance d between the dummy substrate DW and the placement surface 6e is, for example, a distance at which no plasma is generated between the dummy substrate DW and the placement surface 6e in the cleaning of the stage 2 (ST62) which will be described later. In this case, as illustrated in FIG. 7, the plasma P generated in the space defined by the dummy substrate DW and the shower head 16 is diffused between the dummy substrate DW and the electrostatic chuck 6 (including the placement surface 62 and/or the shoulder 6c). In addition, the distance d may be, for example, 0.01 mm or more and 1 mm or less. In addition, the distance d may be 0.2 mm or more and 0.7 mm or less. By maintaining the distance d between the dummy substrate DW and the electrostatic chuck 6 at these distances, as illustrated in FIG. 7, the byproduct adhering to or deposited on the shoulder 6c can be removed by the plasma P diffused between the electric chuck 6 and the electric chuck 6 while suppressing the placement surface 62 from being damaged by the plasma.

Subsequently, in operation ST62, at least a portion of the stage 2 is cleaned. First, a predetermined processing gas is supplied into the chamber 1 in the state in which the dummy substrate DW is held at the position spaced by the predetermined distance d from the placement surface 6e. At this time, the internal pressure of the chamber 1 is reduced to a predetermined pressure. The predetermined pressure may be higher than the pressure in operation ST2 and/or the pressure in operation ST3. The processing gas is generated in the etching of the patterned substrate PW (ST1) and may be appropriately selected depending on the byproduct adhering to or deposited on the shoulder 6c of the electrostatic chuck 6. For example, when the byproduct is a CF-based polymer, the byproduct may be a fluorine-containing gas such as NF₃ or CF₄. In addition, the processing gas may include an O₂ gas. In addition, the processing gas is not limited to the O₂ gas, but may be other oxygen-containing gases such as a CO gas, a CO₂ gas, and an O₃ gas). In addition, when silicon or metal is included as a byproduct in addition to the CF-based polymer, for example, a halogen-containing gas may be added as the processing gas. In addition, the halogen-containing gas may be a chlorine-based gas such as a Cl₂ gas or a bromine-based gas such as a HBr gas.

Subsequently, RF power is supplied to the stage 2 which is a lower electrode. The controller 100 controls the first RF power supply 10a to generate RF power, thereby supplying the RF power to the base material 2a of the stage 2. As a result, plasma is generated from the processing gas supplied into the chamber 1 in the space defined by the dummy substrate DW placed on the placement surface 6e and the shower head 16 which functions as an upper electrode. In addition, a frequency of the RF power generated by the first RF power supply 10a may be, for example, 10 MHz or more and 100 MHz or less, or 40 MHz or more and 100 MHz or less. The RF power in operation ST62 may be, for example, 50 W or more and 10,000 W or less, 100 W or more and 7,000 W or less, or 200 W or more, or 5,000 W or less. In addition, an energy density of the plasma P in operation ST62 may be higher than that of the plasma P in operation ST2. The energy density of the plasma P in operation ST62 may be, for example, 0.10 W/cm² or more and 10 W/cm² or less, 0.11 W/cm² or more and 9 W/cm² or less, or 0.14 W/cm² or more and 8 W/cm² or less. In addition, in operation ST62, a time period during which the plasma P is generated is, for example, 10 seconds or more and 100 seconds or less.

When the plasma P is generated in the space defined by the dummy substrate DW and the shower head 16, a region including the periphery of the placement surface 6e of the electrostatic chuck 6 is cleaned by the plasma P diffused into the space. The region may include, for example, the shoulder 6c. In addition, the byproduct removed from the electrostatic chuck 6 by the cleaning may be adhering to or deposited on the dummy substrate DW.

Subsequently, in operation ST63, the dummy substrate DW is unloaded from the chamber 1. The dummy substrate DW may be unloaded from the chamber 1 and stored in a FOUP of the load port LP. The dummy substrate DW stored in the load port LP may be loaded into the chamber 1 again in the operation of loading the dummy substrate DW (ST4) after the operation of etching the patterned substrate PW (ST1) is newly executed. In addition, the dummy substrate DW may be cleaned again in operation ST5. As a result, the dummy substrate DW used in the second cleaning operation ST6 can be efficiently cleaned.

### Examples

In operation ST62, a photoresist layer formed on the rear surface of the dummy substrate DW (the surface facing the placement surface 6e) was etched while changing the distance d between the dummy substrate DW and the placement surface 6e of the electrostatic chuck 6 is changed from 0.0 mm to 1.0 mm in 0.1 mm increments (hereinafter, each example in which the distance d was changed will also be collectively referred to as “each example”). Conditions for etching the dummy substrate DW are as follows.
Frequency of RF power HF: 40.68 MHz
Output of RF power HF: 2,700 W
Output of RF power LF: 0 W
Pressure: 500 mTorr
Processing gas: O₂ gas (900 sccm), CF₄ gas (50 sccm)
Distance d: written in the graph

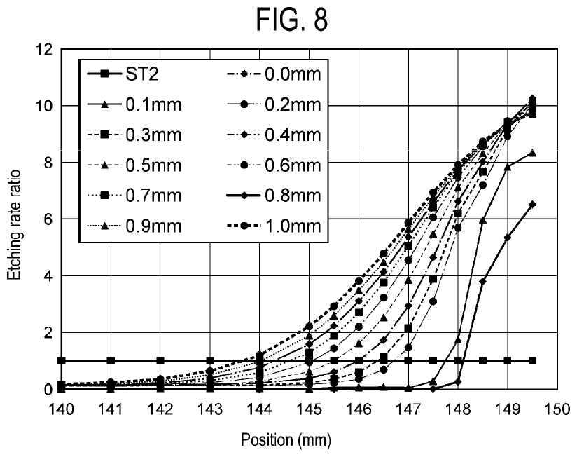

FIG. 8 is a graph obtained by plotting a relationship between an in-plane position of the dummy substrate DW and an etching rate of a photoresist layer in each example. The dummy substrate DW is a silicon wafer with a diameter of 300 mm, and has a photoresist layer formed on its surface. In FIG. 8, the horizontal axis represents the in-plane position of the dummy substrate DW, that is, a position from the center of the dummy substrate DW. In addition, the vertical axis represents the etching rate ratio of the photoresist layer. The etching rate ratio is a ratio of the etching rate in each example to the etching rate in operation ST2 (in FIG. 8, the etching rate in each example was standardized by setting the etching rate in operation ST2 to 1). In addition, the etching rate in operation ST2 is the etching rate obtained by etching the photoresist layer formed on the surface of the dummy substrate DW (the surface facing the shower head 16) under the conditions of cleaning the stage 2 in operation ST2 in the state in which the dummy substrate D2 is placed on the placement surface 6e.

According to the present embodiment, as illustrated in FIG. 8, while obtaining a high etching rate in the outer peripheral portion of the dummy substrate DW (e.g., the portion spaced outward by 148 mm from the center of the dummy substrate DW), that is, the periphery of the placement surface 63 of the electrostatic chuck 6 (e.g., the shoulder 6c), it was possible to suppress the etching rate at the edge of the placement surface 63 of the electrostatic chuck 6 (e.g., a portion corresponding to the vicinity of 145 mm from the center of the dummy substrate DW). For example, when the distance d is 0.0 mm (i.e., the state in which the dummy substrate DW is in contact with the placement surface 6e), the etching rate of the photoresist layer in the outer peripheral portion of the dummy substrate DW (e.g., at the position of 148 mm) is low. That is, it is considered that the photoresist layer or the byproduct is not removed efficiently in the outer peripheral portion. On the other hand, when the distance d was set to 0.1 mm, the etching rate of the photoresist layer in the outer peripheral portion of the dummy substrate DW (e.g., at the position of 148 mm) was about 8 times the etching rate when the distance d was 0.0 mm. Similarly, when the distance d was set to 0.2 mm, the etching rate of the photoresist layer at the position of 148 mm was approximately three times the etching rate when the distance d was 0.1 mm. Furthermore, it was confirmed that the etching rate of the photoresist layer in the outer peripheral portion of the dummy substrate DW (e.g., the portion outside the position of 145 mm) increases as the distance d increases. The etching rate increased significantly when the distance d was between 0.2 mm and 0.7 mm. Moreover, as illustrated in FIG. 3, it was confirmed that each example was effective in removing the photoresist layer or the byproduct particularly in the outer peripheral portion of the dummy substrate DW, also in comparison with operation ST2.

As described above, in the present embodiment, by setting the distance d between the dummy substrate DW and the placement surface 6e to an appropriate distance, the periphery of the placement surface 6e (e.g., the shoulder 6c) can be cleaned by the diffused plasma P while protecting the placement surface 6e with the dummy substrate DW. In addition, in the present embodiment, since the placement surface 6e can be protected by the dummy substrate DW, the RF power can be increased in operation ST62. Further, since the processing gas such as a fluorine-containing gas can be used, the periphery of the placement surface 6e (e.g., the shoulder 6c) can be cleaned more efficiently by the diffused plasma P. Therefore, in operation ST2, since the placement surface 6e can be efficiently cleaned while suppressing damage to the placement surface 6e, and in operation ST6, since the periphery of the placement surface 6e can be efficiently cleaned while suppressing damage to the placement surface 6e, the efficiency of maintenance of the stage 2 can be improved. Furthermore, since the maintenance time for the stage 2 can be significantly reduced, the throughput of etching can be improved.

In the example illustrated in FIG. 3, the processes from operation ST1 to operation ST6 have been described in this order, but the order in which each operation is executed is not limited thereto. As an example, after executing operation ST5 and/or operation ST6, operation ST2 and/or operation ST3 may be executed. For example, each operation illustrated in FIG. 3 may be executed in the order of operation ST1, operation ST4, operation ST5, operation ST6, operation ST2, and operation ST3. As a result, the placement surface 6e of the electrostatic chuck 6 can be cleaned after the byproduct generated in operation ST1 is removed or reduced in operation ST5 and/or operation ST6.

Furthermore, operation ST5 may be executed after executing operation ST4 and operation ST6. As a result, even if a byproduct is deposited on or adheres to the dummy substrate DW in operation ST6, the byproduct on the dummy substrate DW can be removed or reduced in operation ST5.

Each of the above-described embodiments has been described for illustrative purposes, and various modifications may be made without departing from the scope and spirit of the present disclosure. For example, in addition to the capacitively coupled plasma processing apparatus 10, a substrate processing apparatus using any plasma source such as inductively coupled plasma or microwave plasma may be used.

In addition, embodiments of the present disclosure may include the following aspects (1) to (27).
(1) A cleaning method in a plasma processing apparatus, the cleaning method comprising a first cleaning operation and a second cleaning operation, wherein the plasma processing apparatus includes a chamber, a stage provided in an interior of the chamber and having a placement region on which a substrate is placed, and an electrode provided to face the placement region. The first cleaning operation includes supplying a first processing gas to the interior of the chamber, and cleaning a region including the placement region in the stage by generating a first plasma from the first processing gas in a space defined by the placement region and the electrode. The second cleaning operation includes holding a dummy substrate at a predetermined position spaced by a predetermined distance from the placement region to face the placement region, supplying a second processing gas to the interior of the chamber, and cleaning the region including the periphery of the placement region in the stage by generating a second plasma from the second processing gas in a space defined by the dummy substrate held at the predetermined position and the electrode.
(2) In the cleaning method of the aspect (1) above, the first processing gas includes an oxygen-containing gas.
(3) In the cleaning method of the aspect (2) above, the oxygen-containing gas is an O₂ gas.
(4) In the cleaning method of any one of the aspects (1) to (3) above, the second processing gas includes a fluorine-containing gas.
(5) In the cleaning method of the aspect (4) above, the fluorine-containing gas includes a NF₃ gas.
(6) In the cleaning method of the aspect (4) or (5) above, the fluorine-containing gas includes a CₓF_{y} gas (where x and y are positive integers).
(7) In the cleaning method of any one of the aspects (4) to (6) above, the second processing gas includes an O₂ gas.
(8) In the cleaning method of any one of the aspects (1) to (7) above, a modification operation executed between the first cleaning operation and the second cleaning operation, wherein the modification operation includes supplying an inert gas into the interior of the chamber, and modifying the region including the placement region in the stage by generating a plasma from the inert gas in the space defined by the placement region and the electrode.
(9) In the cleaning method of the aspect (8) above, the inert gas is a nitrogen gas, and the region including the placement region in the stage is nitrided by plasma generated from the nitrogen gas.
(10) The cleaning method of any one of the aspects (1) to (9) above further includes a dummy substrate processing operation of cleaning the dummy substrate, wherein the dummy substrate processing operation includes an operation of loading the dummy substrate to the interior of the chamber, an operation of placing the dummy substrate on the placement region, and an operation of cleaning at least the dummy substrate by generating a third plasma from the third processing gas in the space defined by the dummy substrate placed on the placement region and the electrode, and the second cleaning operation is executed after the dummy substrate processing operation.
(11) In the cleaning method of the aspect (10) above, the third processing gas includes a fluorine-containing gas.
(12) In the cleaning method of the aspect (11) above, the fluorine-containing gas includes a NF₃ gas.
(13) In the cleaning method of the aspect (11) or (12) above, the fluorine-containing gas includes a CₓF_{y} gas (where x and y are positive integers).
(14) In the cleaning method of any one of the aspects (11) to (13) above, the third processing gas includes an O₃ gas).
(15) In the cleaning method of any one of the aspects (10) to (14) above, the dummy substrate processing operation includes generating a fourth plasma by supplying RF waves having a first frequency and RF waves having a second frequency to the stage or the electrode.
(16) In the cleaning method of any one of the aspects (10) to (15) above, the operation of the holding the dummy substrate includes moving the dummy substrate placed on the placement region to the predetermined position.
(17) In the cleaning method of any one of the aspects (10) to (15) above, in the operation of loading the dummy substrate, the dummy substrate is loaded into the chamber from a substrate storage. In the operation of the holding the dummy substrate, the dummy substrate loaded into the chamber from the substrate storage is held at the predetermined position. The second cleaning operation further includes, after the operation of cleaning the region including the periphery of the placement region in the stage, an operation of unloading the dummy substrate from the interior of the chamber to the substrate storage.
(18) In the cleaning method of any one of the aspects (1) to (17) above, the predetermined distance is a distance at which no plasma is generated in the space defined by the dummy substrate held at the predetermined position and the placement region.
(19) In the cleaning method of any one of the aspects (1) to (17) above, the predetermined distance is 0.01 mm or more and 1 mm or less from the placement region.
(20) In the cleaning method of any one of the aspects (1) to (19) above, a time period during which the second plasma is generated in the second cleaning operation is 10 seconds or more and 100 seconds or less.
(21) In the cleaning method of any one of the aspects (1) to (20) above, the electrode has the plurality of gas passage holes. In the operation of supplying the second processing gas to the interior of the chamber, the second processing gas is supplied into the chamber from the gas passage holes.
(22) In the cleaning method of any one of the aspects (1) to (21) above, the second plasma has an energy density of 0.1 W/cm² or more and 10 W/cm² or less.
(23) In the cleaning method of any one of the aspects (1) to (22) above, the second plasma has a higher energy density than the first plasma.
(24) In the cleaning method of the aspect (23) above, the first cleaning operation includes generating the first plasma by supplying RF waves having a first power to the stage or the electrode, and the second cleaning operation includes generating the second plasma by supplying RF waves having a second power higher than the first power to the stage or the electrode.
(25) In the cleaning method of the aspect (24) above, the second power is 50 W or more and 10,000 W or less.
(26) A cleaning method in a plasma processing apparatus is provided. The plasma processing apparatus includes a chamber, a stage provided in an interior of the chamber and having a placement region on which a substrate is placed, and an electrode provided to face the placement region. The cleaning method includes an operation of loading a dummy substrate to the interior of the chamber, an operation of holding a dummy substrate at a predetermined position spaced by a predetermined distance from the placement region to face the placement region, an operation of supplying a processing gas to the interior of the chamber, and an operation of cleaning a region including the placement region in the stage by generating plasma from the processing gas in a space defined by the dummy substrate held at the predetermined position and the electrode.
(27) A plasma processing method in a plasma processing apparatus is provided. The plasma processing apparatus includes a chamber, a stage provided in an interior of the chamber and having a placement region on which a substrate is placed, and an electrode provided to face the placement region. The processing method includes an etching operation and a cleaning operation. The etching operation includes preparing a patterned substrate having a layer to be etched and a mask layer formed on the layer to be etched and having a predetermined pattern, placing the patterned substrate on the placement region of the stage, supplying an etching gas to the interior of the chamber, etching the patterned substrate by supplying RF power to the stage or the electrode and generating a plasma from the etching gas in a space defined by the patterned substrate and the electrode, and unloading the patterned substrate from the chamber. The cleaning operation includes loading a dummy substrate different from the patterned substrate into the chamber, holding a dummy substrate at a predetermined position spaced by a predetermined distance from the placement region to face the placement region, supplying a processing gas into the chamber, and cleaning a region including the periphery of the placement region in the stage by generating a plasma from the processing gas in a space defined by the dummy substrate held at the predetermined position and the electrode.

According to an exemplary embodiment of the present disclosure, it is possible to provide a technique for cleaning a stage in a plasma processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A cleaning method in a plasma processing apparatus,
the cleaning method comprising a first cleaning operation and a second cleaning operation,
wherein the plasma processing apparatus includes: a chamber; a stage provided in an interior of the chamber and having a placement region on which a substrate is placed; and an electrode provided to face the placement region,
wherein the first cleaning operation includes:
supplying a first processing gas to the interior of the chamber; and
cleaning a region including the placement region of the stage by generating a first plasma from the first processing gas in a space defined by the placement region and the electrode, and
wherein the second cleaning operation includes:
holding a dummy substrate at a predetermined position spaced by a predetermined distance from the placement region to face the placement region;
supplying a second processing gas to the interior of the chamber; and
cleaning a region including a periphery of the placement region of the stage by generating a second plasma from the second processing gas in a space defined by the dummy substrate held at the predetermined position and the electrode.

2. The cleaning method of claim 1, wherein the first processing gas includes an oxygen-containing gas.

3. The cleaning method of claim 2, wherein the second processing gas includes a fluorine-containing gas.

4. The cleaning method of claim 3, further comprising: a modification operation executed between the first cleaning operation and the second cleaning,
wherein the modification operation includes:
supplying a third processing gas to the interior of the chamber; and
modifying the region including the placement region of the stage by generating a third plasma from the third processing gas in the space defined by the placement region and the electrode.

5. The cleaning method of claim 4, further comprising: a dummy substrate processing operation of cleaning the dummy substrate,
wherein the dummy substrate processing operation includes:
loading the dummy substrate to the interior of the chamber;
placing the dummy substrate on the placement region; and
cleaning at least the dummy substrate by generating a fourth plasma from a fourth processing gas in a space defined by the dummy substrate placed on the placement region and the electrode, and
wherein the second cleaning operation is executed after the dummy substrate processing operation.

6. The cleaning method of claim 5, wherein the fourth processing gas includes a fluorine-containing gas.

7. The cleaning method of claim 6, wherein the fourth processing gas includes an O₂ gas.

8. The cleaning method of claim 7, wherein the holding the dummy substrate includes moving the dummy substrate placed on the placement region to the predetermined position.

9. The cleaning method of claim 7, wherein, in the loading the dummy substrate, the dummy substrate is loaded to the interior of the chamber from a substrate storage,
wherein, in the holding the dummy substrate, the dummy substrate loaded to the interior of the chamber from the substrate storage is held at the predetermined position, and
wherein the second cleaning operation further includes, after the cleaning the region including the periphery of the placement region of the stage, unloading the dummy substrate from the interior of the chamber to the substrate storage.

10. The cleaning method of claim 9, wherein the predetermined distance is a distance at which no plasma is generated in a space defined by the dummy substrate held at the predetermined position and the placement region.

11. The cleaning method of claim 9, wherein the predetermined distance is 0.01 mm or more and 1 mm or less from the placement region.

12. The cleaning method of claim 5, wherein the holding the dummy substrate includes moving the dummy substrate placed on the placement region to the predetermined position.

13. The cleaning method of claim 5, wherein, in the loading the dummy substrate, the dummy substrate is loaded to the interior of the chamber from a substrate storage,
wherein, in the holding the dummy substrate, the dummy substrate loaded to the interior of the chamber from the substrate storage is held at the predetermined position, and
wherein the second cleaning operation further includes, after the cleaning the region including the periphery of the placement region of the stage, unloading the dummy substrate from the interior of the chamber to the substrate storage.

14. The cleaning method of claim 1, wherein the second processing gas includes a fluorine-containing gas.

15. The cleaning method of claim 1, further comprising: a modification operation executed between the first cleaning operation and the second cleaning,
wherein the modification operation includes:
supplying a third processing gas to the interior of the chamber; and
modifying the region including the placement region of the stage by generating a third plasma from the third processing gas in the space defined by the placement region and the electrode.

16. The cleaning method of claim 1, further comprising: a dummy substrate processing operation of cleaning the dummy substrate,
wherein the dummy substrate processing operation includes:
loading the dummy substrate to the interior of the chamber;
placing the dummy substrate on the placement region; and
cleaning at least the dummy substrate by generating a fourth plasma from a fourth processing gas in a space defined by the dummy substrate placed on the placement region and the electrode, and
wherein the second cleaning operation is executed after the dummy substrate processing operation.

17. The cleaning method of claim 1, wherein the predetermined distance is a distance at which no plasma is generated in a space defined by the dummy substrate held at the predetermined position and the placement region.

18. The cleaning method of claim 1, wherein the predetermined distance is 0.01 mm or more and 1 mm or less from the placement region.

19. A cleaning method in a plasma processing apparatus,
wherein the plasma processing apparatus includes:
a chamber;
a stage provided in an interior of the chamber and having a placement region on which a substrate is placed; and
an electrode provided to face the placement region,
wherein the cleaning method comprises:
loading a dummy substrate to the interior of the chamber;
holding a dummy substrate at a predetermined position spaced by a predetermined distance from the placement region to face the placement region;
supplying a processing gas to the interior of the chamber; and
cleaning a region including the placement region of the stage by generating a plasma from the processing gas in a space defined by the dummy substrate held at the predetermined position and the electrode.

20. A plasma processing method in a plasma processing apparatus,
the plasma processing method comprising an etching operation and a cleaning operation,
wherein the plasma processing apparatus includes:
a chamber;
a stage provided in an interior of the chamber and having a placement region on which a substrate is placed; and
an electrode provided to face the placement region,
wherein the etching operation includes:
preparing a patterned substrate having a layer to be etched and a mask layer formed on the layer to be etched and having a predetermined pattern;
placing the patterned substrate on the placement region of the stage;
supplying an etching gas to the interior of the chamber;
etching the patterned substrate by supplying radio frequency power to the stage or the electrode and generating a plasma from the etching gas in a space defined by the patterned substrate and the electrode; and
unloading the patterned substrate from the chamber, and
wherein the cleaning operation includes:
loading a dummy substrate different from the patterned substrate into the chamber,
holding the dummy substrate at a predetermined position spaced by a predetermined distance from the placement region to face the placement region;
supplying a processing gas to the interior of the chamber; and
cleaning a region including a periphery of the placement region of the stage by generating a plasma from the processing gas in a space defined by the dummy substrate held at the predetermined position and the electrode.
